(19) United States
(12) Patent Application Publication
(10) Pub. No.: US 2012/0314486 A1
(43) Pub. Date: Dec. 13, 2012

(54) Semiconductor Memory Device for Reducing Charge/Discharge Power of Write Bitlines

(75) Inventors: Masahiko YOSHIMOTO, Hyogo (JP); Hiroshi KAWAGUCHI, Hyogo (JP); Shunsuke YOSHIMOTO, Hyogo (JP)

(73) Assignee: SEMICONDUCTOR TECHNOLOGY ACADEMIC RESEARCH CENTER, Kanagawa (JP)

(21) Appl. No.: 13/492,231

(22) Filed: Jun. 8, 2012

(30) Foreign Application Priority Data
Jun. 11, 2011 (JP) JP 2011-130757

(51) Int. Cl. G11C 11/00

(52) U.S. Cl. 365/156

(57) ABSTRACT

It is aimed to provide a semiconductor memory device capable of solving a half-select problem in 8Tr SRAMs and, simultaneously, achieving a reduction in charge/discharge power in a half-selected column, which has been a problem with the conventional write-back scheme. An 8Tr SRAM includes 1) a bitline half driver circuit which is capable of reading retention data from read bitline (RBL) of each memory cell of a memory cell group in a column direction and drives the write bitlines only for the memory cells of a half-selected column according to the read data, 2) a selection signal circuit to which an enable signal and a column selection signal of the bitline half driver circuit are input and which activates the bitline half driver circuit, and 3) an equalizer circuit which equalizes the write bitlines of the memory cell group in the column direction and does not precharge the write bitlines.

### TECHNICAL FIELD

The present invention relates to a technology on a semiconductor memory device for reducing charge/discharge power of write bitlines of an SRAM in which a memory cell is configured by eight transistors.

### BACKGROUND ART

In recent years, VLSI has been a key component of various industries and reliability of VLSI installed in computer systems has become more and more important. However, with the miniaturization of a VLSI fabrication process, variations of transistor device characteristics have increased and low-voltage operation reliability of LSI has decreased. In a VLSI fabrication process in the generation of 90 nm or finer, a variation of a threshold voltage of a MOS transistor integrated into an LSI is said to become evident.

Particularly, since an SRAM (Static Random Access Memory) uses MOS transistors smallest in size in each generation, the SRAM is a factor which determines reliability and yield of LSI and it is becoming important to maintain low-voltage operation reliability.

An SRAM in which a memory cell is configured by six transistors (6T SRAM) is configured by adding an access gate (2T) to a latch circuit (4T), and writing and reading are performed using the same access gate. Thus, it is difficult to solve a tradeoff between write and read margins and low-voltage operation reliability is a serious problem.

On the other hand, since the read margin needs not be considered in an SRAM in which a memory cell is configured by eight transistors by adding a read port (2T) to a 6T SRAM (8T SRAM), it is generally known that the 8T SRAM can be mounted in a smaller area than the 6T SRAM in a miniaturized process (non-patent literature 1).

However, while the 8T SRAM can ensure low-voltage operation reliability, power consumption per unit cycle thereof tends to be more than the 6T SRAM having a higher operating voltage. The reason for that is that power overhead and a speed reduction are caused by a write-back scheme for solving a disturb (so-called half-select problem) at the time of writing in the 8T SRAM, thereby increasing a leakage power ratio (see, for example, patent literature 1, non-patent literature 2).

The above half-select problem and the write-back scheme of the 8T SRAM are described later with reference to the drawings.

### PRIOR ART

### Patent Document

[Patent Document 1] JPA 2008/032549

### Patent Document

[Non-Patent Document 1] L. Chang et al, “Stable SRAM Cell Design for the 32 nm Node and Beyond,” VLSI Tech. Papers, pp. 128-129, June 2005.
[Non-Patent Document 2] J. J. Wu et al, “A Large σVTH/VDD Tolerant Zigzag 8T SRAM with Area-Efficient Decoupled Differential Sensing and Fast Write-Back Scheme,” IEEE Symp. VLSI Circuit, Dig. Tech. Papers, pp. 103-104, 2010.

### DISCLOSURE OF THE INVENTION

### Problems to be Solved by the Invention

In the 8T SRAM advantageous in the miniaturized process, the half-select problem can be solved by using the conventional write-back scheme and low-voltage operation reliability can be ensured. However, in the conventional write-back scheme, an increase in charge/discharge power in a half-selected column at the time of a write operation has been problematic due to full swing of all write bitlines.

In view of the above situation, an object of the present. invention is to provide a semiconductor memory device capable of solving a half-select problem in an 8T SRAM and, simultaneously, achieving a reduction in charge/discharge power in a half-selected column, which has been a problem in the conventional write-back scheme.

### Means to Solve the Objects

To achieve the above object, the present invention is directed to a semiconductor memory device in which a plurality of arrayed memory cells are arranged in each of which an access gate is provided in a latch circuit in which two CMOS inverter circuits form a loop, a read-only transistor is further provided and word lines are divided into a read word line (RWL) and a write word line (WWL) and from each of which retention data of the memory cell is readable via a read bitline (RBL) by activating only the read word line (RWL), wherein the semiconductor memory device comprises the following elements 1) to 3).

1) A bitline half driver circuit which is capable of reading retention data from a read bitline (RBL) of each memory cell of a memory cell group in a column direction and drives the write bitlines (WBLs) only for the memory cells of a half-selected column according to the read data.

2) A selection signal circuit to which an enable signal and a column selection signal of the bitline half driver circuit are input and which activates the bitline half driver circuit.

3) An equalizer circuit which equalizes the write bitlines of the memory cell group in the column direction and does not precharge the write bitlines.

According to such a configuration, the half-select problem in 8T SRAMs can be solved and, simultaneously, charge/discharge power in a half-selected column, which has been a problem with the conventional write-back scheme, can be reduced.

The memory cell in which the access gate is provided in the latch circuit in which the two CMOS inverter circuits form a loop, the read-only transistor is further provided, the word lines are divided into the read word line (RWL) and the write word line (WWL) and from which retention data of the memory cell is readable via the read bitline (RBL) by activating only the read word line (RWL) is a memory cell of an 8T SRAM or a memory cell having a similar configuration.

Further, the bitline half driver circuit of the above 1) is specifically configured that a driver part for pulling up and down the write bitlines (WBLs) of the memory cell is composed of nMOSs, and a pulled-up voltage level of the bitline is clamped at a voltage lower than a supply voltage by a threshold value of the nMOS.

Alternatively, the bitline half driver circuit of the above 1) is so configured that the driver part for pulling up and down the write bitlines (WBLs) of the memory cell is composed of inverters, and a pulled-up voltage level of the bitline is clamped at a voltage lower than a supply voltage by a predetermined voltage by making a supply voltage of the inverter lower than the supply voltage of the memory cell by the predetermined voltage.

In this way, in the bitline half driver circuit, the amount of amplitude of the bitlines of the memory cells in the half-selected column not selected by a column decoder becomes smaller than the amount of amplitude of the bitlines of the memory cells selected by the column decoder in driving the write bitlines. This reduces power consumption.

Further, the selection signal circuit of the above 2) is specifically configured using a CMOS NOR gate or a CMOS NAND gate, the enable signal and the column selection signal of the bitline half driver circuit are input thereto, and an output is made to a gate of an access transistor arranged between the bitline half driver circuit and the write bitline of the memory cells.

Further, the equalizer circuit of the above 3) is specifically configured that an nMOS and a pMOS are connected in parallel and an intermediate node of each is connected to the write bitline of the memory cells.

Alternatively, the equalizer circuit of the above 3) is so configured that an nMOS or a pMOS are connected between the write bitlines of the memory cells.

In this way, the write bitlines of the memory cells are set in a floating state and kept at an intermediate potential by leakage currents of the memory cells in a standby state.

Further, in the above semiconductor memory device of the present invention, the write word line is activated after the operation of the enable signal of the bitline half driver circuit, whereby a reduction in charge/discharge power in the half-selected column, which has been a problem with the conventional write-back scheme, is achieved.

Note that one bitline half driver circuit only has to be provided in one memory cell group composed of a plurality of memory cells such as 8×2⁽ⁿ⁻¹⁾ (n is a natural number) memory cells. To minimize area overhead caused by the addition of the bitline half driver circuit, one bitline half driver circuit is provided in one memory cell group composed of a multitude of memory cells. For example, one bitline half driver circuit is provided in any one of memory cell groups composed of 8 memory cells, 16 memory cells, 32 memory cells, 64 memory cells, 128 memory cells or 256 memory cells. In view of attenuation of retention data by the read bitlines and the drive of the write bitlines, an optical number of memory cells may be set.

### Effects of the Invention

According to the present invention, there is an effect of being able to solve the half-select problem in 8T SRAMs and, simultaneously, achieve a reduction in charge/discharge power in the half-selected column, which has been a problem with the conventional write-back scheme, and construct a low power consumption SRAM.

### BRIEF DESCRIPTION OF THE DRAWINGS

FIG. 1 is a block diagram of an SRAM of the present invention.

FIG. 2 is a block diagram of an SRAM.

FIG. 3 is a circuit diagram of the memory cell of the 6T SRAM.

FIG. 4 is a diagram illustrating the operation of the memory cell of the 6T SRAM.

FIG. 5 is a circuit diagram of the memory cell of the 8T SRAM.

FIG. 6 is a circuit diagram at the time of reading from the memory cell of the 8T SRAM.

FIG. 7 is a circuit diagram of a selected cell and an unselected cell at the time of the writing from the memory cell of the 8T SRAM.

FIG. 8 is a conventionally known write-back circuit of the memory cell of the 8T SRAM.

FIG. 9 is a diagram 1 illustrating the operation of the conventionally known write-back circuit.

FIG. 10 is a diagram 2 illustrating the operation of the conventionally known write-back circuit.

FIG. 11 is a circuit configuration diagram including the bitline half driver circuit and the equalizer circuit.

FIG. 12 is a block diagram of the 8T SRAM of the present invention.

FIG. 13 is a diagram illustrating the operation of the bitline half driver circuit.

FIG. 14 shows the comparison of operation waveforms between the conventional technology and the SRAM of the present invention.

FIG. 15 shows a leakage power reduction effect.

FIG. 16 shows an active power reduction effect.

FIG. 17 shows the comparison of a power consumption reduction effect between nMOS-fast corner and nMOS-slow corner.

FIG. 18 shows an active leakage power reduction effect in the trial circuit of the 512 Kb SRAM.

FIG. 19 shows an active power reduction effect at the time of writing in the trial circuit of the 512 Kb SRAM.

FIG. 20 is an illustration of the influence of a random variation of a threshold value.

FIG. 21 is a circuit configuration diagram of other embodiment of the bitline half driver circuit.

FIG. 22 is a circuit configuration diagram of other embodiment of the equalizer circuit FIG. 23 is a circuit configuration diagram of other embodiment of the selection signal circuit.

### BEST MODE FOR CARRYING OUT THE INVENTION

Hereinafter, an embodiment of the present invention will be described with reference to the accompanying drawings. The present invention is not limited to the illustrated construction. The present invention can be variously changed in design.

First, the influence of a random variation of a threshold value is described with reference to FIG. 20. FIG. 20(1) shows a MOS transistor (pass gate) for reading retention data in a memory cell of a 6T SRAM. With the miniaturization of a process, a variation of a threshold voltage of the MOS transistor increases as shown in FIG. 20(2). The variation of the threshold voltage is caused by factors such as a variation of a gate length, impurity fluctuation, temperature and LER (Line Edge Roughness). As shown in FIG. 20(3), a variation of an on-current of the pass gate also increases due to the influence of the variation of the threshold voltage.

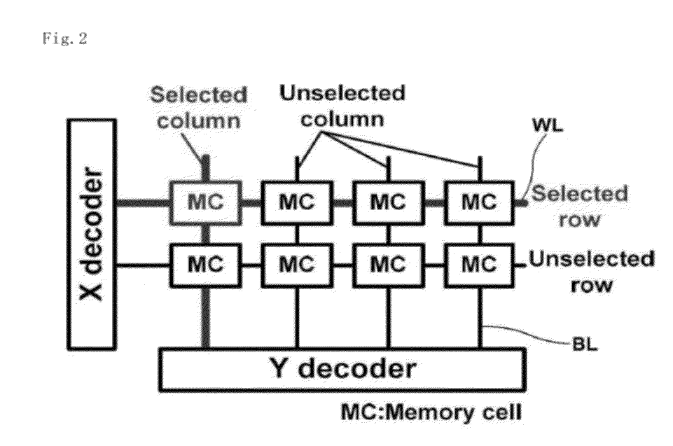

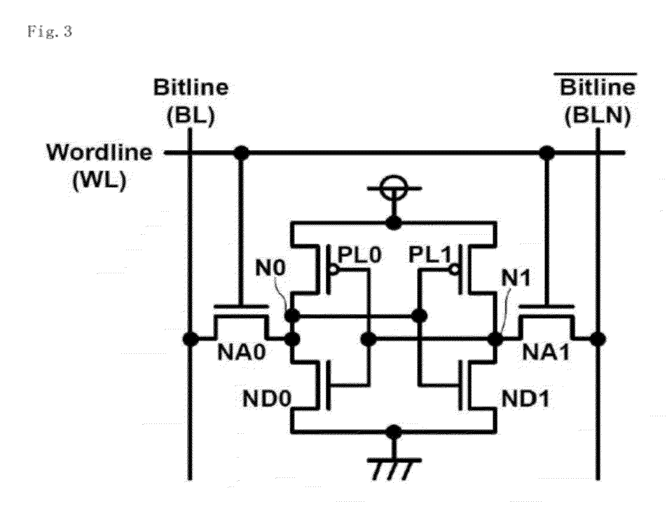

FIG. 2 is a block diagram of an SRAM and FIG. 3 shows a circuit diagram of a memory cell of a general 6T SRAM. The memory cell of the conventional 6T SRAM is composed of load transistors (PL0, PL1), access transistors (NA0, NA1) and drive transistors (ND0, ND1). Further, there are a row selection line (word line) penetrating through the memory cell in a horizontal direction and data lines (bitlines) penetrating in a vertical direction.

As a read operation, the bitlines (BLs) are first precharged and set to “high”. Then, a word line (WL) of a row selected based on an input address signal by an X decoder (not shown) is set up. The access transistors (NA0, NA1) of memory cells of a row selected by an X decoder circuit (not shown) are turned on and retention data are output to the bitlines (BLs). A bitline (BL) of a column selected by a Y decoder circuit is output to a sense amplifier circuit (not shown) to amplify a minute potential difference. An amplified signal is retained by a data latch circuit (not shown) to output data.

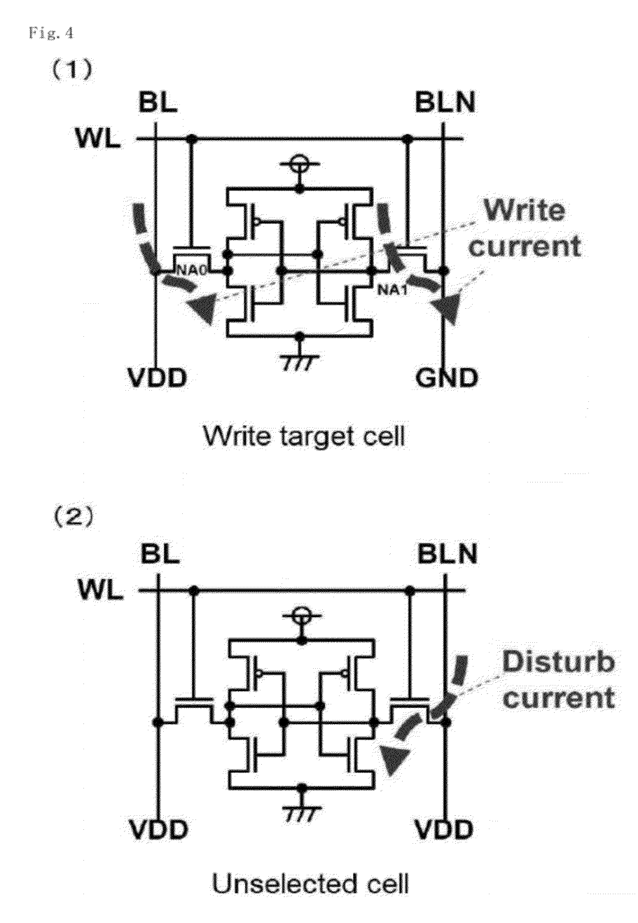

Further, as a write operation, a word line (WL) of a row selected by the X decoder circuit (not shown) is set up based on an input address signal and the Y decoder circuit (not shown) selects a bitline. In accordance with write data, one bitline (BLN) is grounded (GND) by a write driver circuit (not shown) and the other bitline (BL) is driven to a supply voltage (VDD). As shown in FIG. 4(1), the access transistors (NA0, NA1) of memory cells of the row selected by the X-decoder circuit (not shown) are turned on and data is written from the bitline in a write target cell of the column selected by the Y-decoder circuit.

However, as described above, with the further miniaturization of the process, reliability of the operation of the memory cells of the conventional 6T SRAM is being lost. As described above, with the miniaturization of the process, a variation of a threshold voltage of a MOS transistor increases. The conventional 6T SRAM has a great advantage in terms of increasing capacity and speed but, on the other hand, a disturb current occurs in unselected cells, in which data is not to be written, as shown in FIG. 4(2). At this time, the write margin becomes smaller when the threshold values of the access transistors (NA0, NA1) vary to be higher, whereas the read margin becomes smaller when they vary to be lower. That is, in the conventional 6T SRAM, the tradeoff between the read and write margins cannot be solved and a low-voltage operation becomes difficult as the miniaturization progresses.

On the other hand, since the 8T SRAM includes a dedicated read port, the read margin needs not be considered and a yield at low voltage is easily secured. Thus, its necessity has been increased as the miniaturization progresses.

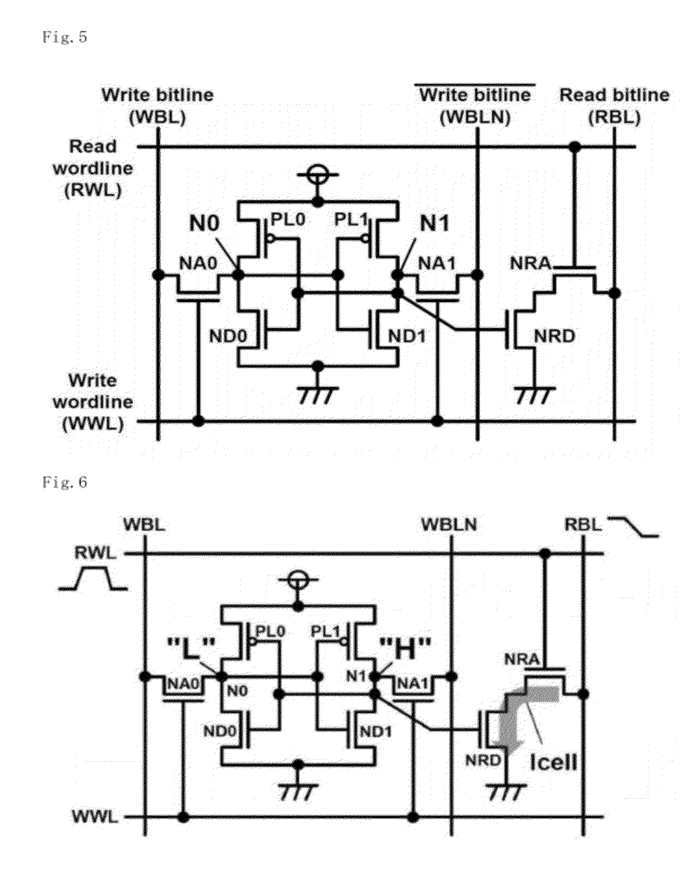

FIG. 5 shows a circuit diagram of the memory cell of the 8T SRAM. In the memory cell of the 8T SRAM, a drive transistor (NRD) of the read port is switched on or off according to a state of potential (VDD or 0V) at a data retention node (N1), and the presence or absence of discharge of electric charges precharged in the read bitline (RBL) changes.

FIG. 6 shows a circuit diagram at the time of reading from the memory cell of the 8T SRAM. When the potential of the data retention node (N1) is VDD, the read drive transistor (NRD) is turned on. When a read word line (RWL) is set up, a discharge path is formed from the read bitline (RBL) to the ground (GND) via a read access transistor (NRA) and the read drive transistor (NRD).

By forming the discharge path, the potential of the read bitline (RBL) is gradually reduced from VDD. The potential of the read bitline (RBL) reaches a logical threshold voltage of an amplifier (not shown) in a subsequent stage, whereby a data output is determined.

Since the potential of the data retention node (N1) is received by a gate of the read drive transistor (NRD) and directly transmitted to the read bitline (RBL) in the read port of the memory cell of the 8T SRAM, retention data is not destroyed by the read operation. That is, the read margin needs not be considered in the design of the memory cell of the 8T SRAM. Further, the write operation in the memory cell of the 8T SRAM is the same as that in the memory cell of the 6T SRAM described above.

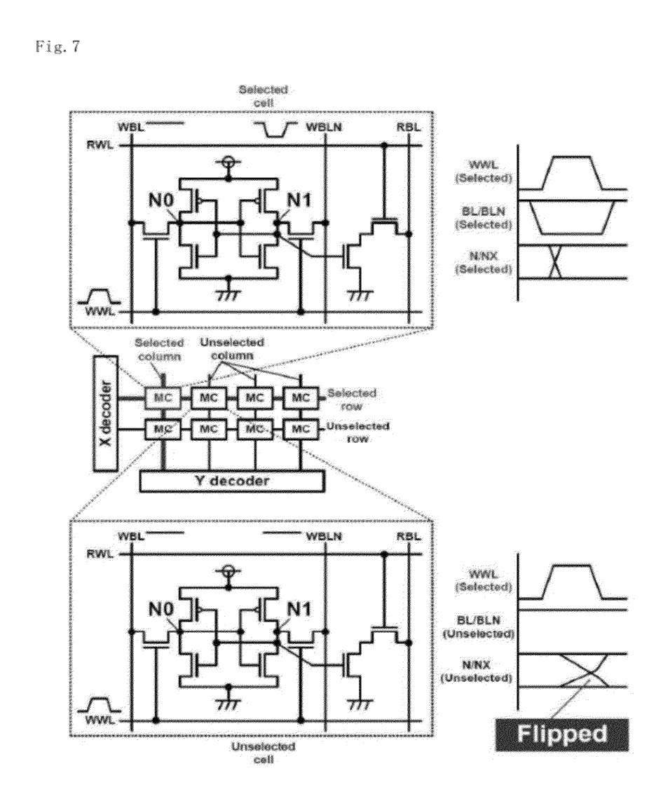

FIG. 7 shows a circuit diagram of a selected cell and an unselected cell at the time of the write operation. Writing in the memory cell of the 8T SRAM is performed through the word line selected in the row direction and the bitline selected in the column direction. The selected bitline fixed at a VDD or GND level by a write driver and writing is performed in the memory cell by driving the selected word line. At this time, memory cells (half-selected cells), in which data are not to be written, are present on the selected word line. Since the bitlines of these half-selected cells are precharged to VDD, a disturb current flows into the nodes kept at the GND level. As a result, there is a half-select problem, in which a bit failure occurs, in the cell whose margin is reduced at low voltage.

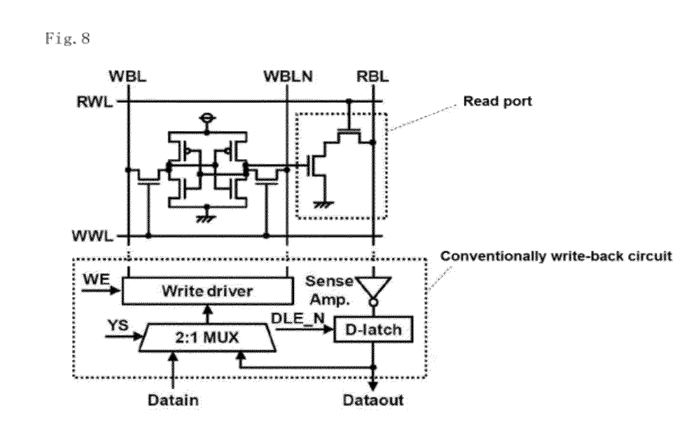

One of techniques for avoiding instability of memory cells in a half-selected column of an 8T SRAM is a write-back scheme. The write-back scheme is described with reference to a conventionally known write-back circuit as shown in FIG. 8. The write-back scheme is characterized in that a read operation is performed in the front half of a write cycle. In a circuit of FIG. 8, a disturb in reading retention data from the memory cell is eliminated by a read port of the 8T SRAM, and a disturb in writing is eliminated by the write-back circuit.

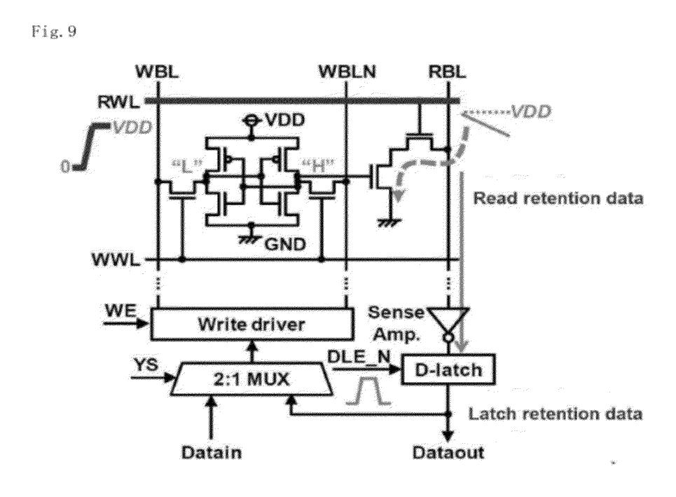

At the time of writing in the memory cell of the 8T SRAM, a read word line (RWL) is first set up and retention data of the memory cells in all columns belonging to a selected row are read to a latch circuit (D-latch) through a read bitline (RBL) as shown in FIG. 9.

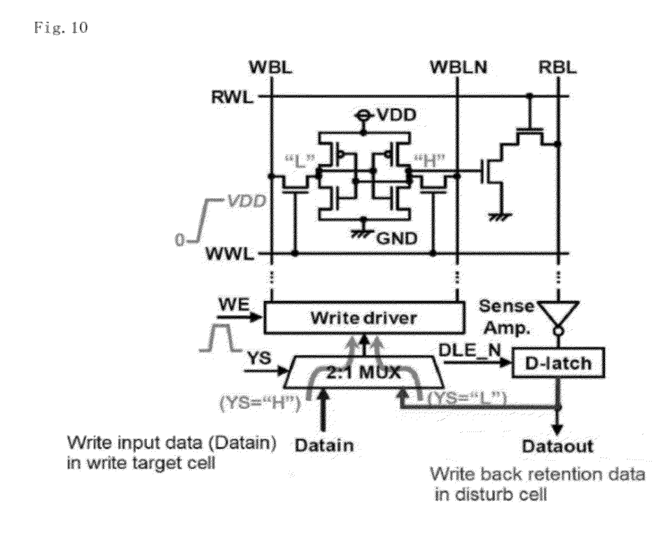

As shown in FIG. 10, in a multiplexer (2:1 MUX), write data are allocated in accordance with column addresses. Input data (Datain) from the outside is allocated to a selected column, and read data (Dataout) are allocated to unselected columns. At this time, in the conventional write-back scheme, the write bitline (WBL) is precharged to VDD and a write driver of each column drives either one of a pair of bitlines to the GND level in accordance with the allocated data. Subsequently, a write word line (WWL) is set up and the allocated data is written in the memory cells. In this way, the input data from the outside is written in the selected column. On the other hand, the read data (Dataout) are written back in the unselected columns. Thus, no disturb current is produced in the unselected columns and the data are retained.

By using the conventional write-back scheme in this way, the half-select problem can be solved and low-voltage operation reliability of the 8T SRAM can be ensured.

However, since the write word line (WWL) is set up and the allocated data is written in each of the selected and unselected columns in the conventional write-back scheme, all the write bitlines (WBLs) undergo a full swing from VDD to the GND level. At this time, if a column address is N bits, the unselected columns are (2^{N}−1)-fold of the selected column. That is, if a column address is 8 bits, charge/discharge power in the unselected columns is (2⁸−1)=255 times as much as charge/discharge power in the selected column. As a result, an increase in charge/discharge power in the half-selected columns becomes problematic at the time of the write operation.

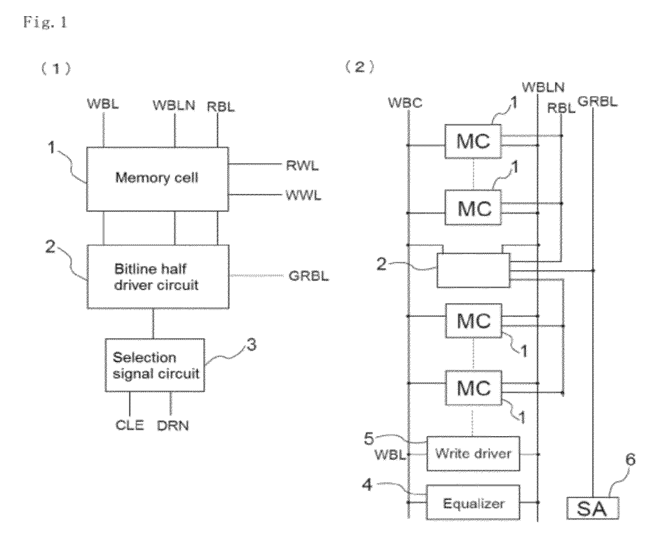

Accordingly, a semiconductor memory device realizing the write-back scheme of the present invention is configured as follows as shown in FIG. 1. The semiconductor memory device is such that a plurality of arrayed memory cells 1 are arranged in each of which an access gate is provided in a latch circuit in which two CMOS inverter circuits form a loop, a read-only transistor is further provided and word lines are divided into a read word line (RWL) and a write word line (WWL) and from each of which retention data of the memory cell is readable via a read bitline (RBL) by activating only the read word line (RWL). The semiconductor memory device includes a bitline half driver circuit 2 which can read retention data from the read bitline (RBL) of each memory cell of a memory cell group in the column direction and drives the write bitlines only for the memory cells of the half-selected column according to the read data, a selection signal circuit 3 to which an enable signal (DRN) and a column selection signal (CLE) of the bitline half driver circuit are input and which activates the bitline half driver circuit, and an equalizer circuit 4 which equalizes the write bitlines of the memory cell group in the column direction and does not precharge the write bitlines.

The amplitudes of the write bitlines (WBLs) are limited by the bitline half driver circuit 2 and the write bitlines (WBLs) can be constantly set in a floating state without being precharged by the equalizer circuit 4. In this way, lower power consumption can be achieved while maintaining an advantage of being able to reduce a lower limit of an operating voltage by the conventional write-back scheme. The semiconductor memory device realizing the write-back scheme of the present invention is characterized in that the write bitlines (WBLs) are precharge-less and the amount of amplitude of the write bitlines (WBLs) is limited.

An implementation method of the semiconductor memory device realizing the write-back scheme of the present invention is as follows. First, data in the selected column are read and input to the bitline half driver circuit. Then, the write bitlines (WBLs) of the unselected columns are charged/discharged by the bitline half driver circuit. Then, writing is performed in the selected column. Finally, the write bitlines (WBLs) are set in the floating state after being equalized.

This is described in detail below, taking a specific circuit as an example.

### Embodiment 1

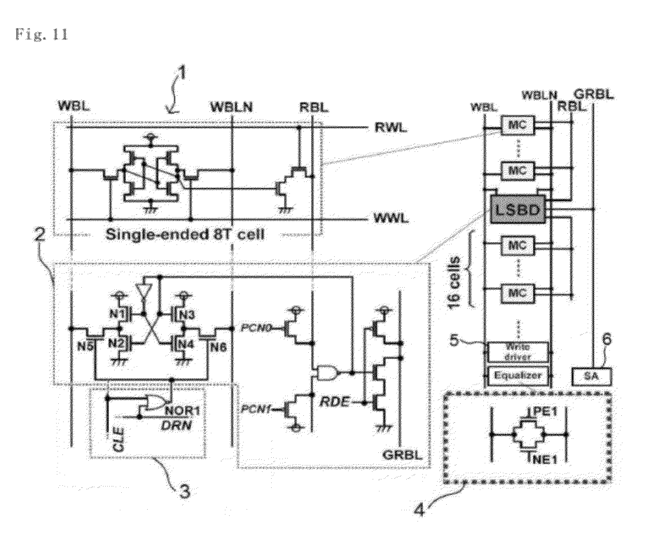

As an embodiment of realizing the write-back scheme of the present invention, a circuit configuration diagram including the bitline half driver circuit and the equalizer circuit is shown in FIG. 11.

The equalizer circuit 4 is a circuit in which an nMOS and a pMOS are connected in parallel and an intermediate node of each is connected to the write bitline of the memory cells. The write bitlines (WBLs) are not precharged and the write bitlines of the memory cells are in the floating state in a standby state. However, the write bitlines are kept at an intermediate potential by leakage currents of the memory cells.

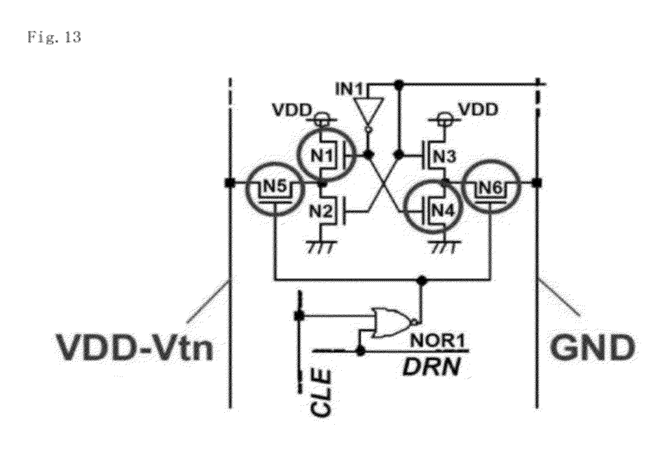

The bitline half driver circuit 2 is located in a stage subsequent to a read circuit for the read bitline (RBL) and drives the write bitlines (WBLs) according to the read data. As shown in FIG. 13, in the bitline half driver circuit 2, a driver part for pulling up and down the write bitlines (WBLs) of the memory cells is composed of four nMOSs (N1, N2, N3 and N4) and is connected to the write bitlines (WBLs) via two access transistors (N5, N6). As described above, since the write bitlines (WBLs) are kept at the intermediate potential lower than a threshold value of the nMOSs before the bitline half driver circuit is operated, a pulled-up voltage level of the bitline is clamped at a voltage lower than the supply voltage by the threshold value of the nMOSs when the transistors (N1, N4, N5 and N6) are switched on, as shown in the figure. In this way, in the bitline half driver circuit, the amount of amplitude of the bitlines of the memory cells of the half-selected column not selected by a column decoder can be made smaller than the amount of amplitude of the bitline of the memory cells selected by the column decoder in driving the write bitlines (WBLs).

Further, the selection signal circuit 3 is configured using a CMOS NOR gate, receives the enable signal (DRN) and the column selection signal (CLE) of the bitline half driver circuit input thereto, and is connected to gates of the access transistors (N5, N6) arranged between the bitline half driver circuit 2 and the write bitlines (WBLs) of the memory cells.

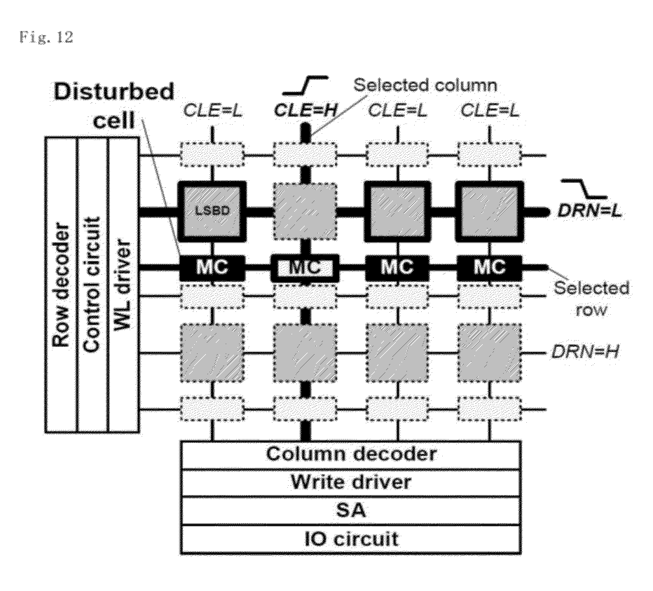

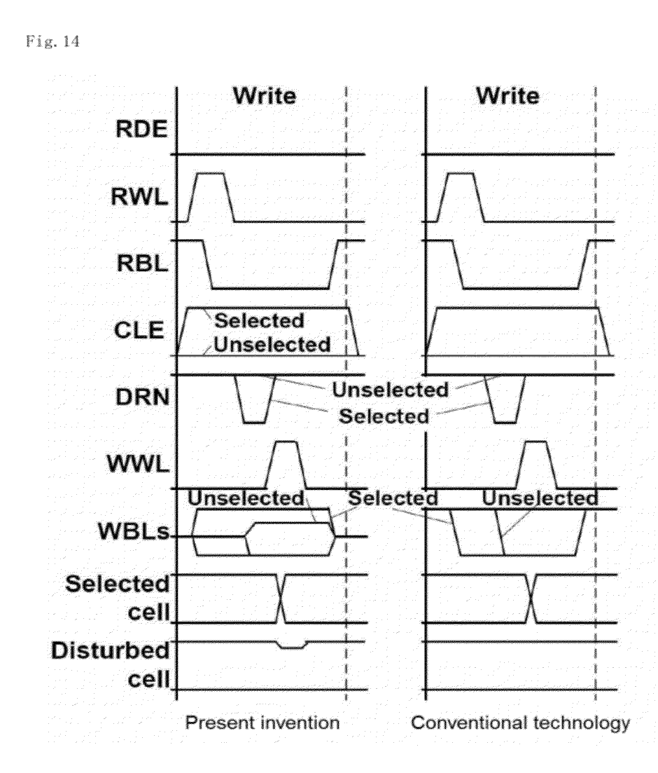

FIG. 12 is a block diagram of the 8T SRAM of the present invention. FIG. 14 is a diagram illustrating the operation of the bitline half driver circuit.

At the time of writing, the read word line (RWL) of the selected row is driven and data are transmitted to the read bitline (RBL). At this time, a column selection signal (CLE) is driven in the selected column where writing is to be performed. Subsequently, in the selected row, a driver enable signal (DRN) is driven. The bitline half driver circuit drives the write bitlines (WBLs) by driving the driver enable signal (DRN) in the unselected columns in which the column selection signal (CLE) is not driven. As a result, in the write target column, the bitline half driver circuit does not drive the write bitlines (WBLs) and drives only the bitlines of the half-selected column. Since the write target column is driven by a write driver configured by a CMOS, the write bitlines (WBLs) are fixed at the VDD and GND levels and data are written as in a conventional manner.

A difference between the conventional technology and the present invention is described in detail using operation waveforms shown in FIG. 14. Between the present invention and the conventional method, there are two points of difference on a voltage waveform of the write bitline (WBL). The first point is that the write bitlines (WBLs) of the selected column (Selected) and the unselected columns (Unselected) are set in the floating state and kept at the intermediate potential in the present invention, but precharged to VDD in the conventional technology. The second point is that the pulled-up potential of the write bitlines (WBLs) in the unselected columns is clamped at the potential lower than VDD by the threshold value of the nMOSs in the present invention, whereas either one of the write bitlines (WBLs) precharged to VDD are pulled down to the GND level in the conventional technology. It is the same that the drive timings of the write bitlines (WBLs) are determined by the column selection signal (CLE) and the driver enable signal (DRN). It is understood that all the write bitlines (WBLs) undergo a full swing in the conventional technology, whereas the amount of amplitude of the write bitlines (WBLs) in the unselected columns are reduced. After the data of the memory cells are reflected on the write bitlines (WBLs) of the half-selected column, the write word line (WWL) is driven to perform writing. At this time, since the pulled-up potential of the write bitline (WBL) is at or below VDD in the present invention, a current path is formed in the write bitline (WBL) from the node held high. However, since the node held low is held by the low-side write bitline (WEL), stability in the half-selected cell (disturbed cell) is maintained. A simulation result to be described later is shown for a yield achieved by using the present invention.

By these operations, the half-select problem can be solved and, simultaneously, a reduction in charge/discharge power in the half-selected column, which has been a problem with the conventional write-back scheme, can be realized.

### (Simulation)

In an SRAM circuit of Embodiment 1, a pull-up write bitline (WBL) is at or below VDD. Thus, a current path may be formed from a node held high to the write bitline (WBL). Accordingly, a yield simulation was carried out on the SRAM circuit of Embodiment 1.

Table 1 below shows a fail bit count simulation result in a half-selected cell. One million Monte-Carlo simulations were tried at each global corner and temperature. As a result of the simulations, a yield of 4.29 σ could be ensured at the worst corner (SS corner and low temperature) and a yield of 4.89 σ or higher was obtained at other corners and temperatures.

TABLE 1

| Fail bit count @ 0.5 V | | Temprature [° C.] | | |
|---|---|---|---|---|
| (1M Monte-Carlo) | | −40 | 25 | 125 |
| Global corner | FF | 0 | 0 | 0 |
| | FS | 0 | 0 | 0 |
| | CC | 0 | 0 | 0 |
| | SF | 0 | 0 | 0 |
| | SS | 19 | 0 | 0 |

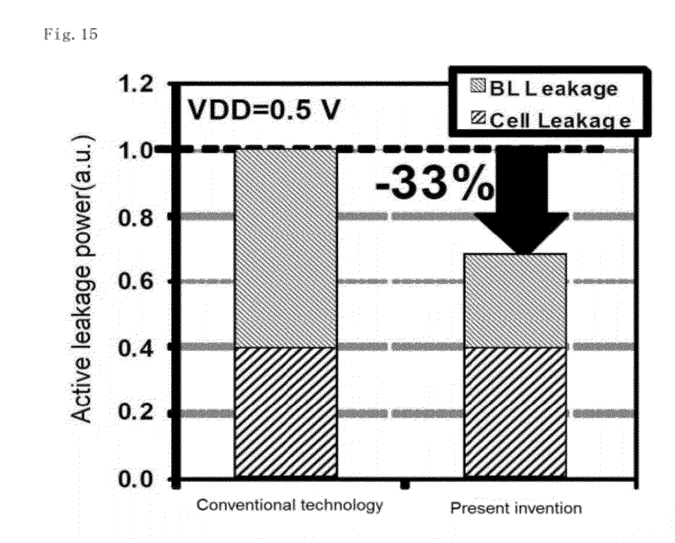

FIG. 15 shows leakage power reduction effects of the SRAM circuit of Embodiment 1 and an 8T SRAM adopting the conventional write-back scheme. Since the write bitlines (WELs) are constantly set in the floating state in the SRAM circuit of Embodiment 1, leakage power in an active state can be reduced. As shown in FIG. 15, leakage power at an FF corner, high temperature and 0.5V operation can be reduced by 33% by the floating of the write bitlines.

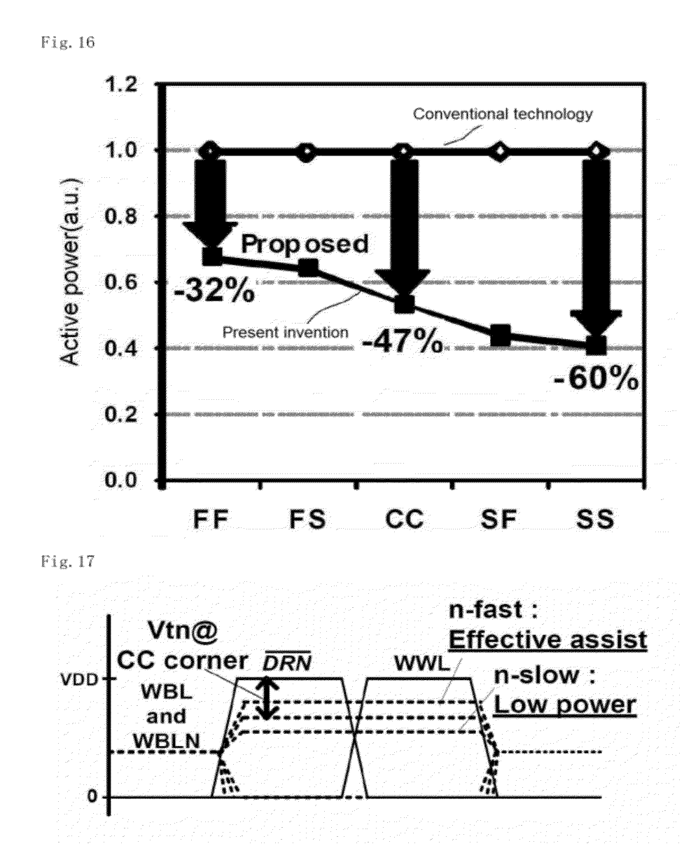

FIG. 16 shows a write active power reduction effect at each global corner. It is understood that active power can be reduced by 32%, 47% and 60% respectively at the FF corner, CC corner and SS corner.

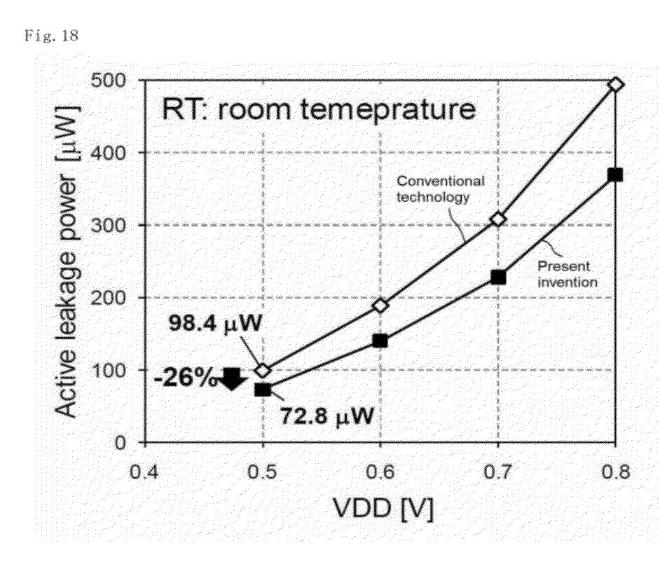

Further, it is understood from FIG. 17 that an assist effect is large, whereas amplitude is large and a power consumption reduction effect is small at an nMOS-fast corner. On the contrary, amplitude is small and the power consumption reduction effect is large at an nMOS-slow corner.

### (Trial Fabrication by 40-nm Process)

The SRAM circuit of Embodiment 1 was prototyped using a 40-nm process. A SRAM memory capacity is 512 Kb, a local read circuit is one in every 16 cells, a bitline half driver circuit is one in every 32 cells and a write driver is one in every 128 cells in a 16 Kb block. Since a read port and a write port are divided in an 8T SRAM, a reduction in power consumption and a higher speed can be achieved by hierarchization of read bitlines.

Table 2 below shows the specification of the prototyped SRAM circuit.

TABLE 2

| | |
|---|---|
| Technology | 40 nm bulk CMOS |
| Macro size | 0.723 mm × 1.010 mm |
| Macro configuration | 512 Kb (16 Kb × 4 × 8), 16 bits/word |
| Cell size | 0.706 μm (logic rule) |
| # of cells/BL | 16 (RBL), 128 (WBL) |
| Density | 701 Kb/mm² |
| Power supply | 0.5-0.8 V |
| Write active power | 8.8 uW/MHz @ 0.5 V, RT |
| Total power (R/W = 50/50) | 20.1 uW/MHz @ 0.5 V, RT |
| Access time | 160 ns @ 0.5 V, 4.5 ns @ 0.8 V |

Since an access time is determined by a read operation, there is no speed overhead due to the bitline half driver circuits and equalizer circuits of the SRAM circuit of Embodiment 1. An access time of 4.5 ns was achieved at 0.8 V and an operation on a single 0.5V power supply was possible.

FIG. 18 shows an active leakage power reduction effect. It is understood that leakage power can be reduced by 26% in a 0.5V operation in the SRAM circuit of Embodiment 1 as compared with the conventional example.

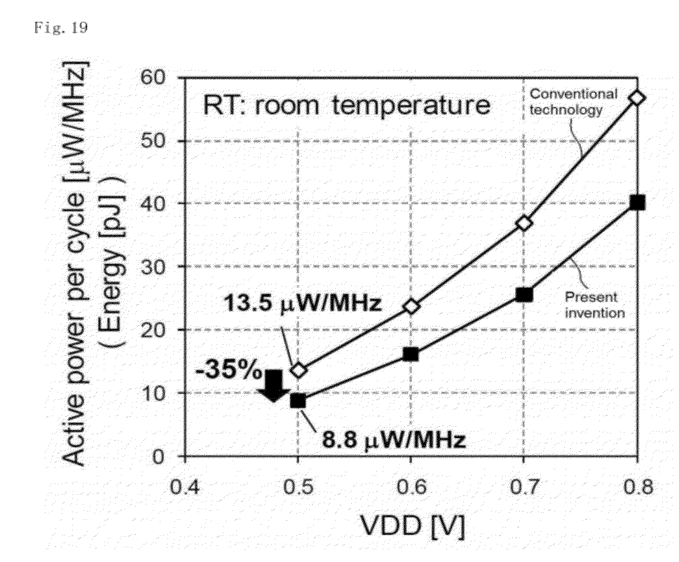

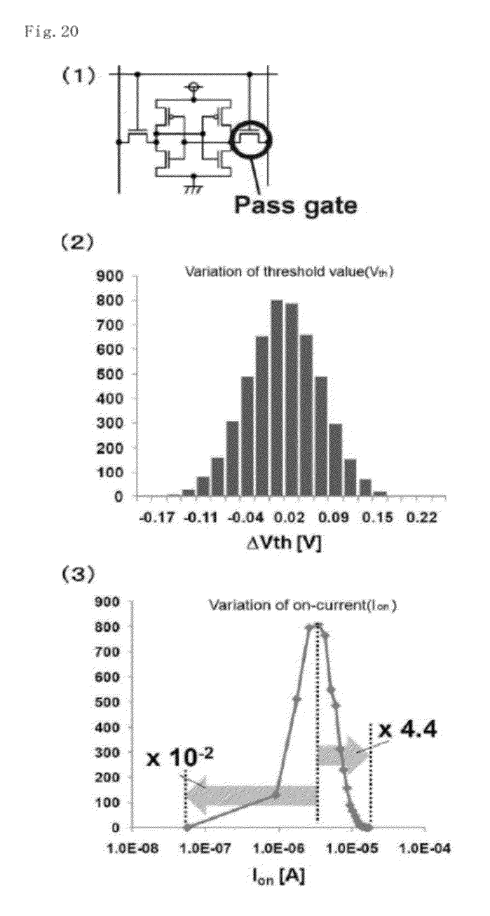

Further, FIG. 19 shows an active power reduction effect at the time of writing. It is understood that active power can be reduced by 35% in the 0.5V operation in the SRAM circuit of Embodiment 1 as compared with the conventional example.

### Other Embodiments

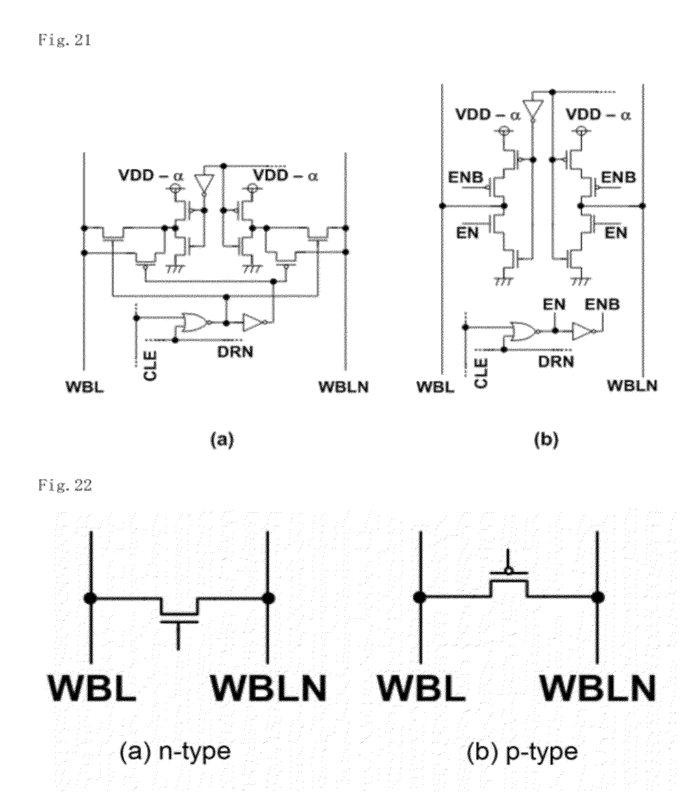

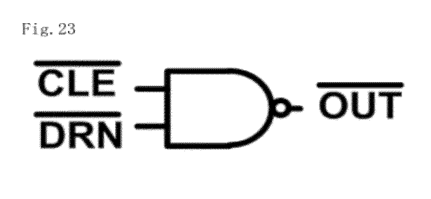

In the above Embodiment 1, the bitline half driver circuit is such that the driver part for pulling up and down the write bitlines (WBLs) of the memory cells is composed of nMOSs and the pulled-up voltage level of the bitline is clamped at the voltage lower than the supply voltage VDD by the threshold value of the nMOSs. However, other configurations may also be adopted. For example, as shown in FIGS. 21(a) and 21(b), a drive part for pulling up and down write bitlines (WBLs) of memory cells may be composed of inverters and the pulled-up voltage level of the bitline may be clamped at a voltage lower than the supply voltage VDD by a predetermined voltage (a) by making a supply voltage of the inverters lower than the supply voltage (VDD) of the memory cells by the predetermined voltage (a).

The bitline half driver circuits shown in FIGS. 21(a) and 21(b) can suppress the amplitudes of the write bitlines (WELs) by making the supply voltage of the inverters lower than that of the memory cells. Specifically, the write bitline (WBL) to be pulled up is driven up to VDD-α by adding a supply voltage of VDD-α to a power supply of the inverters.

Here, in the case of FIG. 21(a), a selection signal circuit for activating the bitline half driver circuit is composed of a CMOS NOR gate and a NOT gate, an enable signal and a column selection signal of the bitline half driver circuit are input to the NOR gate, an output of the NOR gate is output to a gate of an access transistor of the nMOS arranged between the bitline half driver circuit and the write bitline of the memory cell, and an output of the NOT gate is output to a gate of an access transistor of a pMOS arranged between the bitline half driver circuit and the write bitline of the memory cell, respectively. At this time, a similar logic can be constructed even if an NAND gate is used as the selection signal circuit as in FIG. 23.

Further, in the case of FIG. 21(b), a selection signal circuit for activating the bitline half driver circuit is composed of a CMOS NOR gate and a NOT gate, an enable signal and a column selection signal of the bitline half driver circuit are input to the NOR gate, an output of the NOR gate is output to a gate of a conduction switch (nMOS) between an intermediate node of the above inverter configuring the bitline half driver circuit and the nMOS, and an output of the NOT gate is output to a gate of a conduction switch (pMOS) between the intermediate node of the inverter and the pMOS, respectively. At this time, a similar logic can be constructed even if an NAND gate is used as the selection signal circuit as in FIG. 23.

Although the equalizer circuit is so configured that the nMOS and the pMOS are connected in parallel and the intermediate node of each is connected to the write bitline of the memory cells in the above Embodiment 1, another configuration may be adopted provided that the write bitlines of the memory cell group in the column direction are equalized and the write bitlines are not precharged. For example, as shown in FIGS. 22(a) and 22(b), the equalizer circuit may be so configured that the nMOS or the pMOS is connected between the write bitlines of the memory cells.

### INDUSTRIAL APPLICABILITY

The present invention can replace the conventional write-back scheme for 8T SRAMs that has been adopted up to the present.

### DESCRIPTION OF SYMBOLS

1 Memory cell
2 Bitline half driver circuit
3 Selection signal circuit
4 Equalizer circuit
5 Write driver
6 Sense amplifier

1. A semiconductor memory device in which a plurality of arrayed memory cells are arranged in each of which an access gate is provided in a latch circuit in which two CMOS inverter circuits form a loop, a read-only transistor is further provided and word lines are divided into a read word line (RWL) and a write word line (WWL) and from each of which retention data of the memory cell is readable via a read bitline (RBL) by activating only the read word line (RWL), comprising:
a bitline half driver circuit which is capable of reading retention data from the read bitline (RBL) of each memory cell of a memory cell group in a column direction and drives write bitlines (WBLs) only for the memory cells of a half-selected column according to the read data;
a selection signal circuit to which an enable signal and a column selection signal of the bitline half driver circuit are input and which activates the bitline half driver circuit; and
an equalizer circuit which equalizes the write bitlines of the memory cell group in the column direction and does not precharge the write bitlines.

2. The semiconductor memory device according to claim 1, w herein the bitline half driver circuit is so configured that a driver part for pulling up and down the write bitlines (WBLs) of the memory cell is composed of nMOSs, and a pulled-up voltage level of the bitline is clamped at a voltage lower than a supply voltage by a threshold value of the nMOSs.

3. The semiconductor memory device according to claim 1, w herein the bitline half driver circuit is so configured that a driver part for pulling up and down the write bitlines (WBLs) of the memory cell is composed of inverters, and a pulled-up voltage level of the bitline is clamped at a voltage lower than a supply voltage by a predetermined voltage by making a supply voltage of the inverters lower than the supply voltage of the memory cell by the predetermined voltage.

4. The semiconductor memory device according to claim 2, wherein the amount of amplitude of the bitlines of the memory cells of the half-selected column not selected by a column decoder is smaller than the amount of amplitude of the bitlines of the memory cells selected by the column decoder in driving the write bitlines in the bitline half driver circuit, thereby being able to reduce power consumption.

5. The semiconductor memory device according to claim 1, w herein the equalizer circuit is so configured that an nMOS and a pMOS are connected in parallel and an intermediate node of each is connected to the write bitline of the memory cells.

6. The semiconductor memory device according to claim 1, w herein the equalizer circuit is so configured that an nMOS or a pMOS are connected between the write bitlines of the memory cells.

7. The semiconductor memory device according to claim 1, wherein the write bitlines of the memory cells are set in a floating state and kept at an intermediate potential by leakage currents of the memory cells in a standby state.

8. The semiconductor memory device according to claim 1, w herein the selection signal circuit is configured using a CMOS NOR gate or a CMOS NAND gate, the enable signal and the column selection signal of the bitline half driver circuit are input thereto, and an output is made to a gate of an access transistor arranged between the bitline half driver circuit and the write bitline of the memory cells.

9. The semiconductor memory device according to claim 1, w herein the write word line is activated after the operation of the enable signal of the bitline half driver circuit.

10. The semiconductor memory device according to claim 3, wherein the amount of amplitude of the bitlines of the memory cells of the half-selected column not selected by a column decoder is smaller than the amount of amplitude of the bitlines of the memory cells selected by the column decoder in driving the write bitlines in the bitline half driver circuit, thereby being able to reduce power consumption.
